(19) United States
(12) Patent Application Publication
(10) Pub. No.: US 2018/0115312 A1
(43) Pub. Date: Apr. 26, 2018

(54) CHIP WIDE POWER MULTIPLEXER DEPLOYMENT WITH PROGRAMMABLE SWITCH OVER TIME

(71) Applicant: QUALCOMM Incorporated, San Diego, CA (US)

(72) Inventor: Joshua Chin-Pueh Ong, Valley Center, CA (US)

(21) Appl. No.: 15/331,355

(22) Filed: Oct. 21, 2016

(51) Int. Cl. H03K 17/693; H02J 3/00

(52) U.S. Cl. CPC H03K 17/693; H02J 3/005

(57) ABSTRACT

One aspect of the present disclosure relates to a power system. The power system includes a plurality of power multiplexers, wherein each one of the plurality of power multiplexers is configured to selectively couple a respective one of a plurality of circuits to a first supply voltage or a second supply voltage. The power system also includes a power controller coupled to the plurality of power multiplexers, wherein the power controller is configured to send each one of the plurality of power multiplexers a respective one of a plurality of timer values, and a switching sequence for the plurality of power multiplexers is configured based on the plurality of timer values.

### BACKGROUND

### Field

Aspects of the present disclosure relate generally to power multiplexers, and more particularly, to power multiplexers with programmable switching.

### Background

Power multiplexers may be deployed on a chip to provide localized power control of circuits on the chip. The power multiplexer may be used to switch the circuits between a first supply voltage and a second supply voltage. For example, the first supply voltage may be used to power the circuits in an active mode, and the second supply voltage may be used to power the circuits in a low power mode, in which the second supply voltage is lower than the first supply voltage. In this example, the power multiplexers may switch the circuits from the first supply voltage to the second supply voltage when the circuits transition from the active mode to the low power mode, and switch the circuits from the second supply voltage to the first supply voltage when the circuits transition from the low power mode to the active mode.

### SUMMARY

The following presents a simplified summary of one or more embodiments in order to provide a basic understanding of such embodiments. This summary is not an extensive overview of all contemplated embodiments, and is intended to neither identify key or critical elements of all embodiments nor delineate the scope of any or all embodiments. Its sole purpose is to present some concepts of one or more embodiments in a simplified form as a prelude to the more detailed description that is presented later.

According to a first aspect, a power system is provided. The power system includes a plurality of power multiplexers, wherein each one of the plurality of power multiplexers is configured to selectively couple a respective one of a plurality of circuits to a first supply voltage or a second supply voltage. The power system also includes power controller coupled to the plurality of power multiplexers, wherein the power controller is configured to send each one of the plurality of power multiplexers a respective one of a plurality of timer values, and a switching sequence for the plurality of power multiplexers is configured based on the plurality of timer values.

A second aspect relates to a method for power switching. The method includes sending each one of a plurality of power multiplexers a respective one of a plurality of timer values, the plurality of timer values specifying a switching sequence for the plurality of power multiplexers. The method also includes transmitting a start signal to the plurality of power multiplexers, wherein, in response to the start signal, each one of the power multiplexers switches a respective circuit from a first supply voltage to a second supply voltage according to the respective timer value.

A third aspect relates to a method for power switching. The method includes receiving a timer value, receiving a start signal, and, in response to the start signal, starting a timer, wherein the timer is driven by a clock signal. The method also includes switching a circuit from a first supply voltage to a second supply voltage when the timer counts a number of clock cycles approximately equal to the received timer value.

To the accomplishment of the foregoing and related ends, the one or more embodiments comprise the features hereinafter fully described and particularly pointed out in the claims. The following description and the annexed drawings set forth in detail certain illustrative aspects of the one or more embodiments. These aspects are indicative, however, of but a few of the various ways in which the principles of various embodiments may be employed and the described embodiments are intended to include all such aspects and their equivalents.

### BRIEF DESCRIPTION OF THE DRAWINGS

FIG. 1 shows an example of a power multiplexer.

FIG. 2 shows an exemplary deployment of power multiplexers on a chip according to circuit aspects.

FIG. 3 illustrates an example of a switching sequence resulting in multiple punch throughs of hard macros on a chip according to certain aspects according to certain aspects of the present disclosure.

FIG. 4 shows an exemplary power system including multiple power multiplexers with a programmable switching sequence according to certain aspects of the present disclosure.

FIG. 5 illustrates an example of a switching sequence that avoids the multiple punch throughs shown in FIG. 3 according to certain aspects of the present disclosure.

FIG. 6 shows another exemplary power system including multiple power multiplexers with a programmable switching sequence according to certain aspects of the present disclosure.

FIG. 7 is a flowchart illustrating an exemplary method for power switching according to certain aspects of the present disclosure.

FIG. 8 is a flowchart illustrating another exemplary method for power switching according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

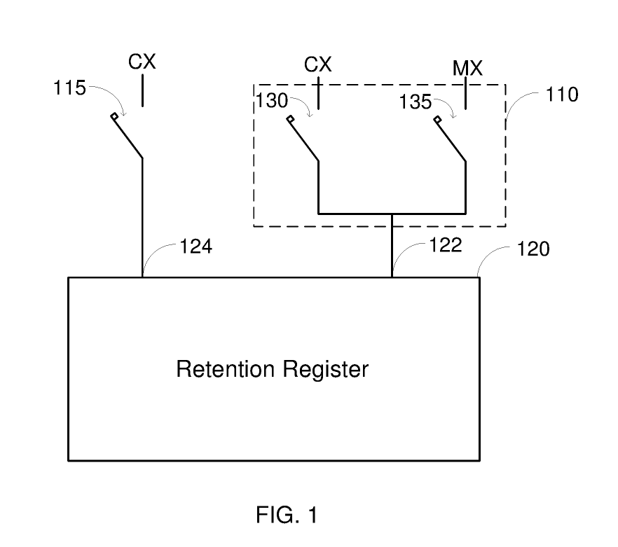

FIG. 1 shows an example of a power multiplexer 110 and a power gate 115 configured to provide localized power control of a retention register 120 (e.g., retention flip-flop) on a chip. The power multiplexer 110 includes a first switch 130 and a second switch 135. The first switch 130 is configured to selectively couple a first supply input 122 of the retention register 120 to a first supply voltage (denoted “CX”), and the second switch 135 is configured to selectively couple the first supply input 122 of the retention register 120 to a second supply voltage MX. The first supply voltage CX is higher than the second supply voltage MX. The power gate 115 is configured to selectively couple a second supply input 124 of the retention register 120 to the first supply voltage CX.

The first supply input 122 may be used to power circuitry in the retention register 120 configured to store a logic state of the register 120 in a low power mode (also referred to as a sleep mode). The second supply input 124 may be used to power circuitry in the retention register 120 configured to receive bits, latch the bits in the register 120, and output the bits from the register 120.

When the retention register 120 is in an active mode, the power multiplexer 110 couples the first supply input 122 of the retention register 120 to the first supply voltage CX. In this case, the first switch 130 is closed (turned on) and the second switch 135 is opened (turned off). Also, the power gate 115 couples the second supply input 124 of the retention register 120 to the first supply voltage CX.

When the retention register 120 transitions to the low power mode, the power multiplexer 110 switches the first supply input 122 of the retention register 120 from the first supply voltage CX to the second supply voltage MX by opening (turning off) the first switch 130 and closing (turning on) the second switch 135. The second supply voltage MX is high enough to enable the retention register 120 to retain its current logic state, but typically not high enough to operate the register 120 in the active mode. Since the second supply voltage MX is lower than the first supply voltage CX, power consumption is reduced. The retained logic state allows the system incorporating the register 120 to return to the active mode without having to reload the logic state of the register 120.

Also, when the retention register 120 transitions to the low power mode, the power gate 115 decouples the second supply input 124 of the register 120 from the first supply voltage CX. This powers off circuitry in the register 120 that receives power from the second supply input 124. Typically, this circuitry is not needed to retain the logic state of the register in the low power mode, and can therefore be powered off in the low power mode to reduce power leakage.

When the retention register 120 transitions from the active mode to the low power mode, the second supply voltage MX is on before the second switch 135 turns on (closes). In other words, the supply rail providing the second supply voltage MX is brought up to the second supply voltage MX before the second switch 135 turns on (closes). In this example, the second switch 135 is coupled between the supply rail providing the second supply voltage MX and the first supply input 122.

Although one retention register 120 is shown in FIG. 1 for ease of discussion, it is to be appreciated that the power multiplexer 110 may be coupled to multiple registers to provide localized power control of the multiple registers.

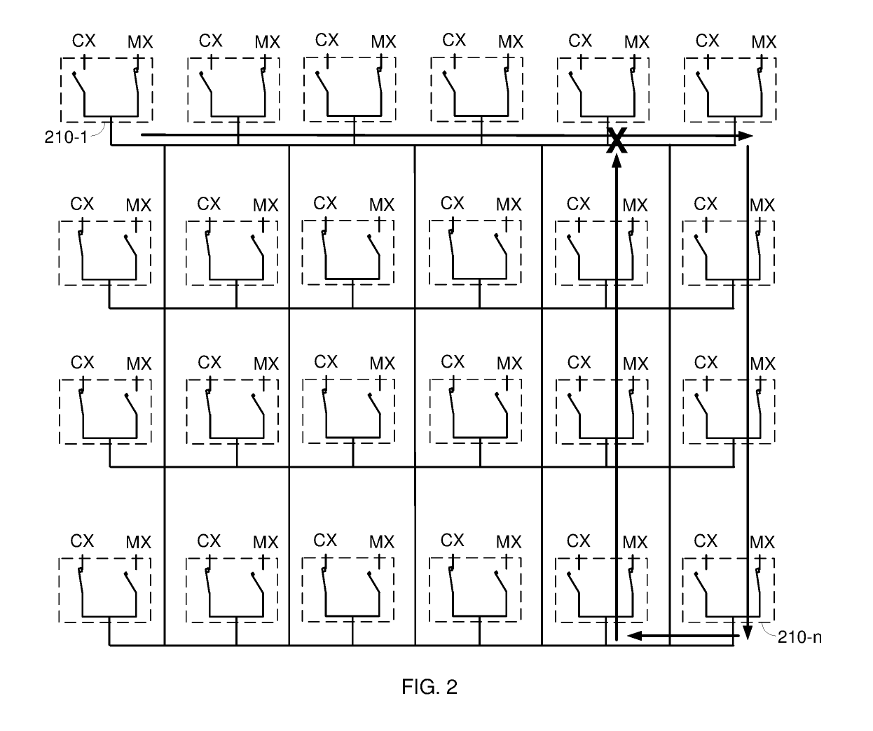

Multiple power multiplexers may be deployed on a chip. In this regard, FIG. 2 shows an example of multiple power multiplexers 210-1 to 210-n distributed on a power network 220 coupled to multiple retention registers (not shown) and/or other circuits (not shown) on a chip. When a system incorporating the registers transitions from the active mode to the low power mode, the power multiplexers 210-1 to 210-n may switch from the first supply voltage CX to the second supply voltage MX sequentially. In this regard, FIG. 2 includes arrows showing an example of a switching sequence for the power multiplexers.

There may be one or more constraints on allowable switching sequences for the power multiplexers. One constraint is that a switching sequence cannot have a loop back, which creates a short circuit between the CX and MX supply rails. In this regard, the exemplary switching sequence indicated by the arrows in FIG. 2 results in an impermissible loop back indicated by a large “X” in FIG. 2.

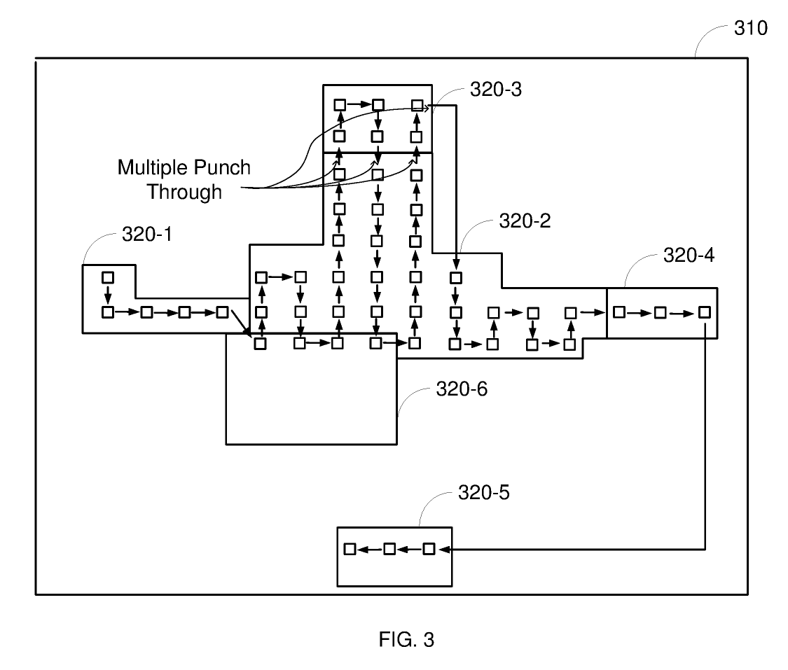

For a chip with multiple hard macros, it is undesirable to have a switching sequence that results in multiple punch throughs of a hard macro. A hard macro may be a functional circuit block that is optimized for power, performance and/or layout for a particular IC manufacturing process. FIG. 3 shows an example of a chip 310 with multiple hard macros 320-1 to 320-6, in which the boundaries of the different hard macros 320-1 to 320-6 are shown in FIG. 3. In FIG. 3, exemplary power multiplexers are depicted as small squares, and an exemplary switching sequence for the power multiplexers is indicated by the arrows between the power multiplexers. As shown in FIG. 3, the switching sequence spans multiple hard macros 320-1 to 320-6 on the chip, and therefore crosses multiple hard macro boundaries. In this example, the switching sequence results in multiple punch throughs (e.g., multiple entry points and multiple exit points) of the hard macros 320-2, 320-3 and 320-6. The locations of the multiple punch throughs for hard macro 320-3 are indicated in FIG. 3.

Multiple punch throughs are undesirable because they waste routing and area resources in high density integrated circuits as multiple ports need to be duplicated for the multiple punch throughs. The duplicate ports take up area at the hard macro boundaries and take up valuable signal routing resources.

In frontend design with a Register Transfer Level (RTL), one set of input and output ports for a hard macro are specified. As backend designers (e.g., layout designers) create multiple punch throughs in the hard macros, extra sets of input and output ports need to be duplicated in the RTL to accommodate the multiple punch throughs. This can create a lot of disruption by requiring a modification of the RTL code. Examples of disruptions caused by the creation of multiple punch throughs include: a need to change test bench to account for the new ports, a need to redo Design for Test (DFT) to account for the new ports, and extra buffering of new signals, which typically requires extra inverters and/or repeaters that take up chip area.

Therefore, it is desirable for a switching sequence for multiple power multiplexers to avoid loop backs and multiple punch throughs. A challenge with meeting these constraints is that a switching sequence is typically hard-wired on a chip (e.g., implemented using a hard-wired delay chain). As a result, it is difficult to change a switching sequence if it is discovered that the switching sequence results in a loop back and/or multiple punch throughs.

To address the above problems, embodiments of the present disclosure provide systems and methods for programming a switching sequence for multiple power multiplexers, as discussed further below.

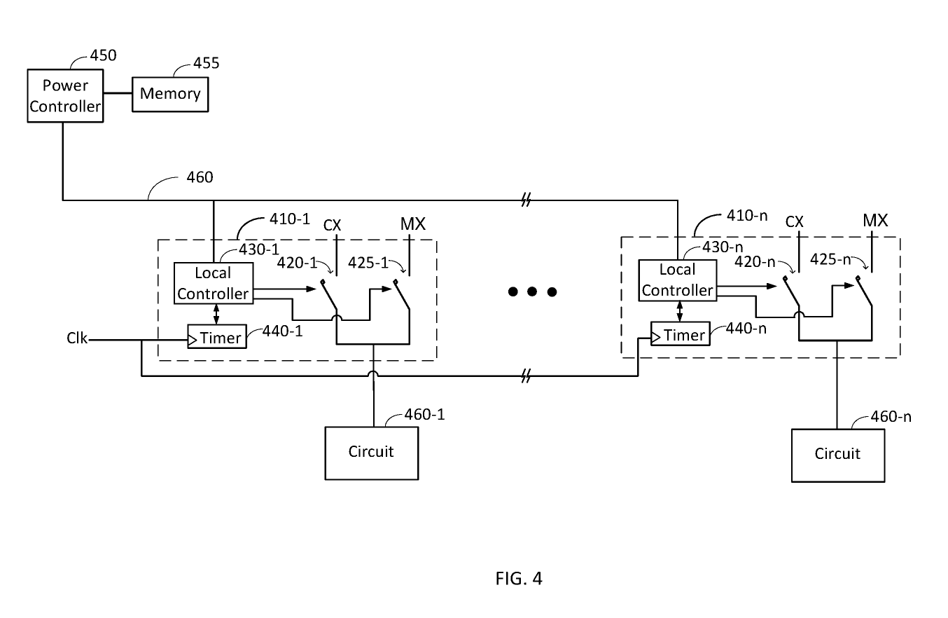

FIG. 4 shows an example of a power system with a programmable switching sequence according to certain aspects of the present disclosure. The power system includes a power controller 450, and multiple power multiplexers 410-1 to 410-n. The power multiplexers 410-1 to 410-n may be distributed on a chip.

Each of the power multiplexers 410-1 to 410-n includes a first switch 420-1 to 420-n configured to selectively couple a respective circuit 460-1 to 460-n to a first supply voltage CX, and a second switch 425-1 to 425-n configured to selectively couple the respective circuit 460-1 to 460-n to a second supply voltage MX. The first supply voltage CX is higher than the second supply voltage MX. For example, the first supply voltage CX may be at least 10 percent higher than the second supply voltage MX. Each of the circuits 460-1 to 460-n may include one or more retention registers (e.g., retention flip-flops) and/or other circuits.

In this example, each of the power multiplexers 410-1 to 410-n is configured to couple the respective circuit 460-1 to 460-n to the first supply voltage CX when the system is in the active mode. Each of the power multiplexers 410-1 to 410-n is also configured to switch the respective circuit from the first supply voltage CX to the second supply voltage MX when the system transitions from the active mode to the low power mode (also referred to as the sleep mode). The second supply voltage MX may be high enough to enable the circuits 460-1 to 460-n to retain their current logic states in the low power mode, but may not be high enough for the circuits to operate in the active mode. As discussed further below, when the system transitions from the active mode to the low power mode, the power multiplexers 410-1 to 410-n may switch over to the second supply MX sequentially according to a programmable switching sequence.

It is to be appreciated that certain portions of the circuits 460-1 to 406-n may be powered off in the low power mode using power gates (not shown in FIG. 4). These portions of the circuits are typically not needed for the circuits to retain their logic states in the low power mode and can therefore be powered off in the low power mode to reduce power leakage. As example of a power gate is illustrated in FIG. 1 and discussed above.

Each of the power multiplexers 410-1 to 410-n also includes a local controller 430-1 to 430-n and a local timer 440-1 to 440-n driven by a clock signal Clk. The local controller 430-1 to 430-n of each power multiplexer 410-1 to 410-n is coupled to the power controller 450 via one or more control lines 460 for communicating with the power controller 450, as discussed further below. Each of the timers 440-1 to 440-n may be implemented by a counter driven by the clock signal Clk.

In operation, the power controller 450 is configured to program a switching sequence for sequentially switching the power multiplexers 410-1 to 410-n from the first supply voltage CX to the second supply voltage MX. To do this, the power controller 450 retrieves timer values for the power multiplexers 410-1 to 410-n from a memory 455, in which the timer values specify the switching sequence. More particularly, each timer value corresponds to a respective one of the power multiplexers 410-1 to 410-n, and specifies when the respective power multiplexer 410-1 to 410-n is to switch from the first supply voltage CX to the second supply voltage MX after reception of a start signal transmitted by the power controller 450. For example, a power multiplexer with a lower timer value switches from the first supply voltage CX to the second supply voltage MX before a power multiplexer with a higher timer value. Since each timer value specifies when the respective power multiplexer 410-1 to 410-n switches from CX to MX, the timer values specify the order in which the power multiplexers switch from CX to MX, and hence specify the switching sequence of the power multiplexers. The power controller 450 sends the timer values to the power multiplexers 410-1 to 410-n via the one or more control lines 460 to program the timer values into the power multiplexers, as discussed further below.

In certain aspects, each power multiplexer 410-1 to 410-n is assigned a unique identification (ID). In these aspects, the power controller 450 uses the IDs to address the timer values so that each power multiplexer receives the correct timer value (i.e., the timer value intended for the power multiplexer). For example, the power controller 450 may address a timer value to a particular power multiplexer by appending the ID assigned to the power multiplexer to the timer value. This allows the power multiplexer to recognize that the timer value is addressed to the power multiplexer. For example, when the power controller 450 transmits a timer value with an ID on the one or more control lines 460, the local controller 430-1 to 430-n of each power multiplexer may compare the transmitted ID with the ID assigned to the power multiplexer to determine whether there is a match. In this example, the local controller of the power multiplexer with the matching ID determines a match, and therefore recognizes that the timer value is addressed to the power multiplexer.

The local controller 430-1 to 430-n of each power multiplexer 410-1 to 401-n may store the respective timer value in a local memory (not shown) and/or program the respective timer value in the respective timer, as discussed further below. Thus, each power multiplexer is programmed with the respective timer value, which specifies (controls) when the power multiplexer is to switch from the first supply voltage CX to the second supply voltage MX upon reception of the start signal.

To initiate the switching sequence, the power controller 450 transmits the start signal to the power multiplexers 410-1 to 410-n via the one or more control lines 460 and/or one or more other control lines. For example, the power controller 450 may receive an instruction from a power manager (not shown) to transition the system from the active mode to the low power mode, and transmit the start signal in response to the instruction.

Upon receiving the start signal, the local controller 430-1 to 430-n of each power multiplexer 410-1 to 410-n starts the respective timer 440. For example, the local controller may preset the respective timer to the respective timer value, and trigger the respective timer to start counting down from the respective timer value upon receiving the start signal. The local controller may then switch the respective circuit from the first supply voltage CX to the second supply voltage MX when the respective timer expires (e.g., count value of the timer reaches zero). The local controller switches from the first supply voltage CX to the second supply voltage MX by opening (turning off) the respective first switch and closing (turning on) the respective second switch. Thus, in response to receiving the start signal from the power controller 430-1 to 430-n, each of the power multiplexer 410-1 to 410-n switches from the first supply voltage CX to the supply voltage supply MX according to the respective timer value.

Therefore, the power controller 450 can program the power multiplexers 410-1 to 410-n to switch from CX to MX according to a desired switching sequence by programming corresponding timer values into the power multiplexer 410-1 to 410-n, in which each timer value controls when the respective power multiplexer switches from CX to MX in the switching sequence.

Accordingly, embodiments of the present disclosure provide great flexibility in programming a switching sequence for the power multiplexers 410-1 to 410-n that meets the constraints discussed above (e.g., no loop back and/or multiple punch throughs). The programmability of the switching sequence allows the switching sequence to be easily changed to adapt to different floor plans (e.g., different hard macro boundaries) while meeting the above constraints.

For example, a designer may determine a switching sequence for the power multiplexers 410-1 to 410-n that avoids loop backs and/or multiple punch throughs (e.g., for a particular floor plan). After determining the switching sequence, the designer may determine timer values for the power multiplexers 410-1 to 410-n according to the order in which the power multiplexers 410-1 to 410-n switch from CX to MX in the sequence. In this regard, a power multiplexer that switches from CX to MX earlier in the switching sequence is given a lower timer value than a power multiplexer that switches from CX to MX later in the switching sequence. After the timer values are determined, the timer values may be written to the memory 455. In operation, the power controller 450 retrieves the timer values from the memory 455, and programs the timer values into the power multiplexers 410-1 to 410-n so that the power multiplexers switch from CX to MX according to the switching sequence.

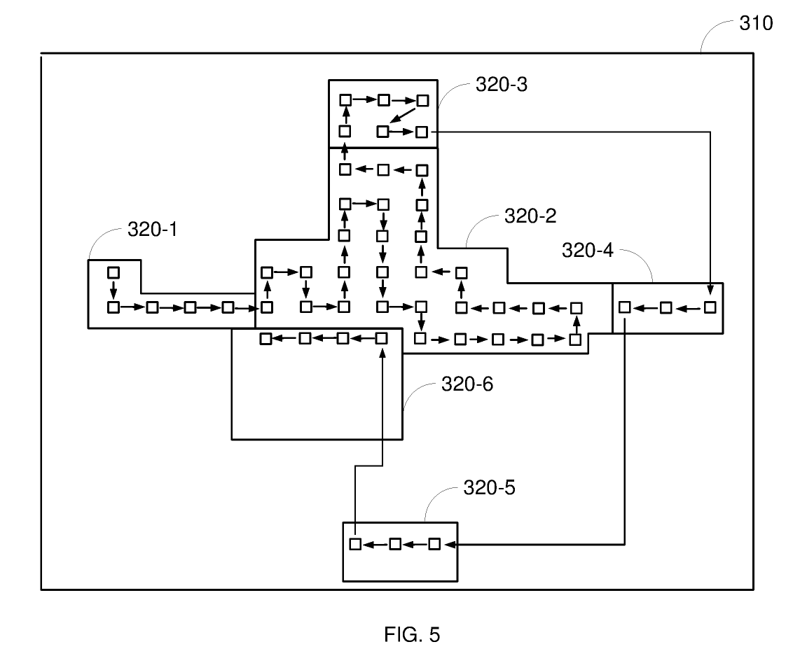

As discussed above, the exemplary switching sequence shown in FIG. 3 results in multiple punch throughs (e.g., multiple entry and multiple exit points) of the hard macros 320-2, 320-3 and 320-6. Embodiments of the present disclosure allow a designer to program a different switching sequence for the power multiplexers that avoids the multiple punch throughs. In this regard, FIG. 5 shows an example in which a different switching sequence is programmed for the same power multiplexers and hard macros shown in FIG. 3. As shown in FIG. 5, the exemplary switching sequence in FIG. 5 avoids the multiple punch throughs shown in FIG. 3. In other words, the exemplary switching sequence results in a single entry point and/or single exit point for each of the hard macros.

As discussed above, the timer value for a particular power multiplexer controls when the power multiplexer switches from the first supply voltage CX to the second supply voltage MX. In the example discussed above, the local controller of the power multiplexer presets the respective timer (e.g., counter) to the respective timer value, triggers the respective timer to start counting down from the respective timer value upon receiving the start signal, and switches from the first supply voltage CX to the second supply voltage MX when the respective timer expires (e.g., count value of the timer reaches zero). However, it is to be appreciated that the present disclosure is not limited to this example.

In another example, the local controller of the power multiplexer may trigger the respective timer to start counting up (e.g., from zero) upon receiving the start signal, and switch from the first supply voltage CX to the second supply voltage MX when the count value of the timer reaches the respective timer value.

In both of the above examples, the timer may be implemented with a counter driven by the clock signal Clk, and the timer value may be in the form of a count value. In general, the local controller of the power multiplexer may start the respective timer in response to the start signal, and switch between the first supply voltage CX and the second supply voltage MX when the respective timer counts a number of clock cycles (periods) approximately equal to the respective timer value. This may be accomplished by having the respective timer count down from the respective timer value to zero, or count up from zero to the respective timer value.

Embodiments of the present disclose not only allow a designer to control the order in which the power multiplexers 410-1 to 410-n switch in a sequencing sequence, but also control the amount of time (delay) between switching of adjacent power multiplexers in the switching sequence. For example, the amount of time between switching of adjacent power multiplexers in the switching sequence may be increased by increasing the difference between their timer values.

Embodiments of the present disclosure are discussed above using the example in which the power system transitions from the active state to the low power state. It is to be appreciated that embodiments of the present disclosure may also be used in cases where the power system transitions from the low power mode to the active mode.

For example, the power controller 450 may program a switching sequence for switching the power multiplexers 410-1 to 410-n from the second supply voltage MX to the first supply voltage CX. In this example, the power controller 450 may retrieve timer values for the power multiplexers 410-1 to 410-n from the memory 455, in which the timer values specify the switching sequence. The power controller 450 may then program the timer values into the power multiplexers 410-1 to 410-n, as discussed above.

To initiate the switching sequence, the power controller 450 transmits the start signal to the power multiplexers 410-1 to 410-n via the one or more control lines 460 and/or one or more other control lines. For example, the power controller 450 may receive an instruction from the power manager (not shown) to transition the system from the low power mode back to the active mode, and may transmit the start signal in response to the instruction.

In response to the start signal, the power multiplexers 410- to 410-n sequentially switch from the second supply voltage MX to the first supply voltage CX according to their respective timer values, as discussed above. Each power multiplexer switches from the second supply voltage MX to the first supply voltage CX by opening (turning off) the respective second switch and closing (turning on) the respective first switch.

In some embodiments, the same switching sequence may be used for both switching the power multiplexers from CX to MX when the system transitions from the active mode to the low power mode, and switching the power multiplexers from MX to CX when the system transitions from the low power mode to the active mode. This allows the same timer values to be used for both cases (i.e., allows the timer values to be programmed once for both cases).

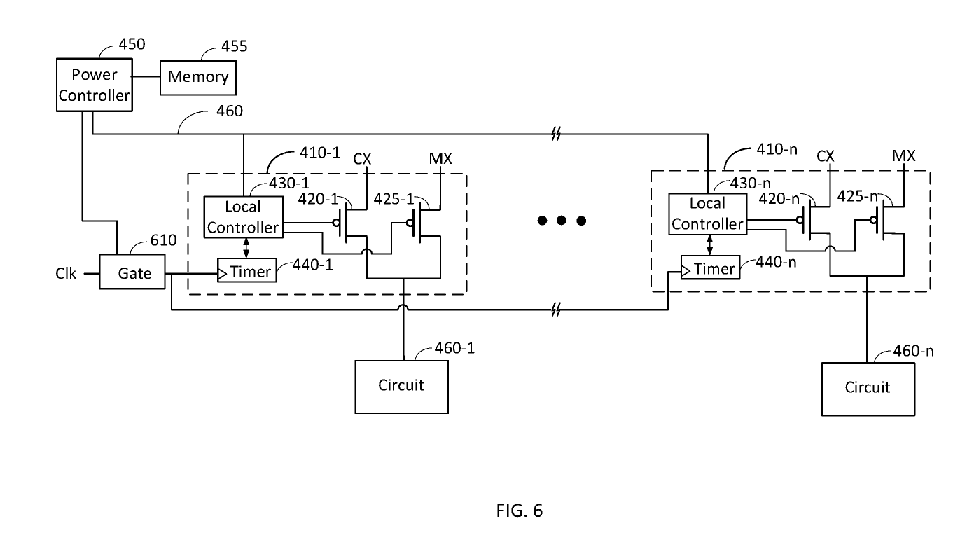

In some embodiments, the first and second switches in each of the power multiplexers 410-1 to 410-n are implemented with p-type field effect transistors (PFETs). In this regard, FIG. 6 shows an example in which each of the switches is implemented with an PFET. More particularly, the first switch 420-1 to 420-n in each of the power multiplexers 410-1 to 410-n is implemented with an PFET having a source coupled to the first supply voltage CX, a gate coupled to the respective local controller, and a drain coupled to the respective circuit. In this example, each local controller 430-1 to 430-n closes (turns on) the respective first switch by applying a logic zero to the gate of the respective first switch, and opens (turns off) the respective first switch by applying a logic one to the gate of the respective first switch. The logic one may correspond to a voltage approximately equal to the first supply voltage CX.

The second switch 425-1 to 425-n in each of the power multiplexers 410-1 to 410-n is implemented with an PFET having a source coupled to the second supply voltage MX, a gate coupled to the respective local controller, and a drain coupled to the respective circuit. In this example, each local controller 430-1 to 430-n closes (turns on) the respective second switch by applying a logic zero to the gate of the respective second switch, and opens (turns off) the respective second switch by applying a logic one to the gate of the respective second switch. The logic one may correspond to a voltage approximately equal to the second supply voltage MX.

In some embodiments, the power system may also include a clock gating circuit 610 for selectively gating the clock signal Clk to the timers 440-1 to 440-n. In this example, the power controller 450 may instruct the clock gating circuit 610 to gate (block) the clock signal Clk from the timers 440-1 to 440-n when the system is not in the process of transitioning from the active mode to the low power mode or from the low power mode to the active mode. This is done to conserve power by disabling the timers when they are not being used. When the system transitions from the active mode to the low power mode or from the low power mode to the active mode, the power controller 450 may instruct the clock gating circuit 10 to pass (un-gate) the clock signal Clk to the timers 440-1 to 440-n to enable the timers. This allows the power multiplexers to sequentially switch from CX to MX or from MX to CX according to the respective timer values, as discussed above.

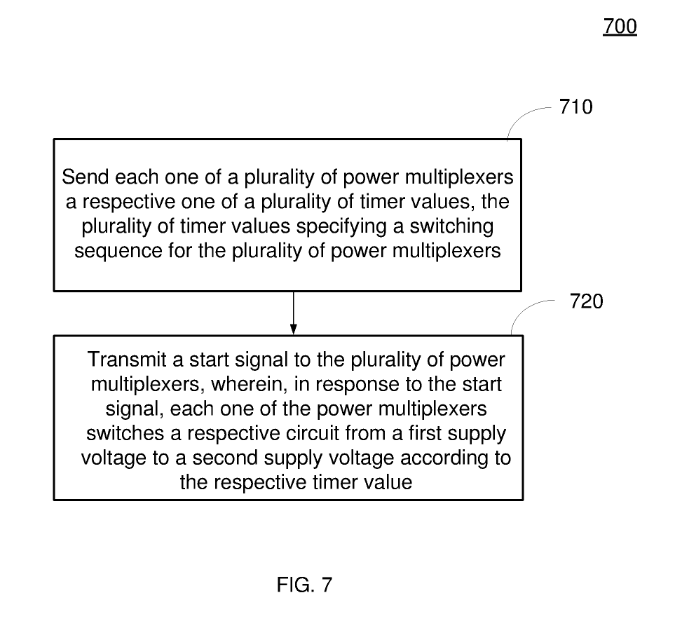

FIG. 7 is a flowchart illustrating a method 700 for power switching according to certain aspects. The method 700 may be performed by the power controller 450.

At step 710, each one of a plurality of power multiplexers is sent a respective one of a plurality of timer values, the plurality of timer values specifying a switching sequence for the plurality of power multiplexers. The power multiplexers may correspond to power multiplexers 410-1 to 410-n. In one example, each of the timer values may be addressed to the respective power multiplexer by appending an ID assign to the respective power multiplexer to the timer value.

At step 720, a start signal is transmitted to the plurality of power multiplexers, wherein, in response to the start signal, each one of the power multiplexers switches a respective circuit from a first supply voltage to a second supply voltage according to the respective timer value. For example, the start signal may be transmitted in response to an instruction to transition from an active mode to a low power mode. In this example, the first supply voltage may be at least 10 percent higher than the second supply voltage.

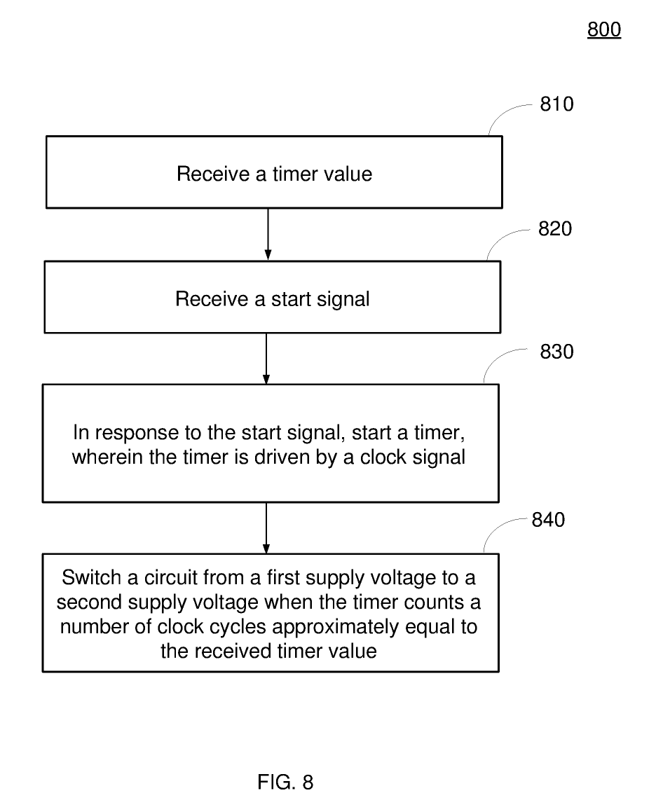

FIG. 8 is a flowchart illustrating a method 800 for power switching according to certain aspects. The method 800 may be performed by one of the power multiplexers 410-1 to 410-n.

At step 810, a timer value is received. For example, the timer value may be received from a power controller (e.g., power controller 450).

At step 820, a start signal is received. For example, the start signal may be received from the power controller (e.g., power controller 450).

At step 830, in response to the start signal, a timer is started, wherein the timer is driven by a clock signal. For example, the timer may start from a count value equal to the received timer value and count down, or may start from a count value of zero and count up.

At step 840, a circuit is switched from a first supply voltage to a second supply voltage when the timer counts a number of clock cycles approximately equal to the received timer value. For example, this may occur when timer counts down to zero or when the timer counts up to the received timer value. In one example, the first supply voltage may be at least 10 percent higher than the second supply voltage. In this example, the circuit may include at least one register, and the second supply voltage may be high enough to allow the at least one register to retain its current logic state, but may not be high enough to operate the circuit in an active mode.

Each of the power controller 450 and local controllers 430-1 to 430-n according to any of the embodiments discussed above may be implemented with a general-purpose processor, a digital signal processor (DSP), an application specific integrated circuit (ASIC), a field programmable gate array (FPGA) or other programmable logic device, discrete hardware components, or any combination thereof designed to perform the functions described herein. A general-purpose processor may be a microprocessor, but in the alternative, the processor may be any conventional processor, controller, microcontroller, or state machine. A processor may perform the functions described herein by executing software comprising code for performing the functions. The software may be stored on a computer-readable storage medium, such as a RAM, a ROM, an EEPROM, an optical disk, and/or a magnetic disk.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

1. A power system, comprising:
a plurality of power multiplexers, wherein each one of the plurality of power multiplexers is configured to selectively couple a respective one of a plurality of circuits to a first supply voltage or a second supply voltage; and
a power controller coupled to the plurality of power multiplexers, wherein the power controller is configured to send each one of the plurality of power multiplexers a respective one of a plurality of timer values, and a switching sequence for the plurality of power multiplexers is configured based on the plurality of timer values.

2. The power system of claim 1, wherein the power controller is configured to transmit a start signal to the plurality of power multiplexers, and, in response to the start signal, each one of the power multiplexers is configured to switch the respective circuit from the first supply voltage to the second supply voltage according to the respective timer value.

3. The power system of claim 2, wherein each one of the plurality of power multiplexers comprises a respective timer driven by a clock signal, and wherein each one of the plurality of power multiplexers is configured to start the respective timer in response to the start signal, and to switch the respective circuit from the first supply voltage to the second supply voltage when the respective timer counts a number of clock cycles approximately equal to the respective timer value.

4. The power system of claim 2, wherein the first supply voltage is at least 10 percent higher than the second supply voltage.

5. The power system of claim 4, wherein each one of the plurality of power multiplexers is configured to couple the respective circuit to the first supply voltage in an active mode, and to couple the respective circuit to the second supply voltage in a low power mode.

6. The power system of claim 5, wherein each one of the plurality of circuits comprises at least one register configured to retain a logic state of the at least one register in the low power mode.

7. The power system of claim 5, wherein the power controller is configured to receive an instruction to transition from the active mode to the low power mode, and to transmit the start signal in response to the instruction.

8. The power system of claim 1, wherein each one of the plurality of power multiplexers has a different timer value.

9. The power system of claim 1, wherein each one of the plurality of power multiplexers is assigned an identification (ID), and wherein the power controller is configured to send each one of the plurality of timer values with the ID assigned to the respective power multiplexer.

10. The power system of claim 1, wherein the plurality of power multiplexers and the plurality of circuits are on a single chip.

11. A method for power switching, comprising:
sending each one of a plurality of power multiplexers a respective one of a plurality of timer values, the plurality of timer values specifying a switching sequence for the plurality of power multiplexers; and
transmitting a start signal to the plurality of power multiplexers, wherein, in response to the start signal, each one of the power multiplexers switches a respective circuit from a first supply voltage to a second supply voltage according to the respective timer value.

12. The method of claim 11, wherein the first supply voltage is at least 10 percent higher than the second supply voltage.

13. The method of claim 12, further comprising receiving an instruction to transition from an active mode to a low power mode, wherein transmitting the start signal to the plurality of power multiplexers is performed in response to the instruction.

14. The method of claim 11, wherein each one of the plurality of power multiplexers has a different timer value.

15. The method of claim 11, wherein each one of the plurality of power multiplexers is assigned an identification (ID), and wherein sending each one of the plurality of power multiplexers the respective one of the plurality of timer values comprises sending each one of the plurality of timer values with the ID assigned to the respective power multiplexer.

16. A method for power switching, comprising:
receiving a timer value;
receiving a start signal;
in response to the start signal, starting a timer, wherein the timer is driven by a clock signal; and
switching a circuit from a first supply voltage to a second supply voltage when the timer counts a number of clock cycles approximately equal to the received timer value.

17. The method of claim 16, wherein the first supply voltage is at least 10 percent higher than the second supply voltage.

18. The method of claim 17, wherein the circuit comprises at least one register configured to retain a logic state of the at least one register when the circuit is coupled to the second supply voltage.

19. The method of claim 16, wherein receiving the timer value comprises:
receiving a plurality of timer values, wherein each one of the plurality of timer values is received with a different identification (ID); and
determining one of the plurality of timer values that is received with an ID matching a particular ID.

20. The method of claim 16, wherein the timer counts down from the received timer value, and wherein switching the circuit from the first supply voltage to the second supply voltage comprises switching the circuit from the first supply voltage to the second supply voltage when the timer counts down to zero.
